(19) United States
(12) Patent Application Publication
(10) Pub. No.: US 2005/0214660 A1
(43) Pub. Date: Sep. 29, 2005

(54) Negative dye-containing curable composition, color filter and method of producing the same

(75) Inventor: Toru Yamada, Shizuoka-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/088,749

(22) Filed: Mar. 25, 2005

(30) Foreign Application Priority Data
Mar. 25, 2004 (JP) 2004-90649

(51) Int. Cl. G03F 9/00

(52) U.S. Cl. 430/7; 430/270.1

(57) ABSTRACT

There are provided a negative dye-containing curable composition comprising an alkali-soluble binder, an organic solvent-soluble dye, a photopolymerizable compound, a photopolymerization initiator, an organic solvent and at least one of higher fatty acids and derivatives thereof, a color filter produced by using the negative dye-containing curable composition and a method of producing the color filter.

### CROSS-REFERENCE TO RELATED APPLICATION

This application claims priority under 35USC 119 from Japanese Patent Application No. 2004-90649, the disclosures of which is incorporated by reference herein.

### BACKGROUND OF THE INVENTION

1. Field of the invention

The present invention relates to a negative dye-containing curable composition suitable for forming colored images constituting color filters used for liquid crystal display elements (CVD), solid state image pick-up elements (for example, CCD and CMOS) and the like, also to a color filter using the negative dye-containing curable composition and, further, to a method of producing the color filter.

2. Description of the Related Art

As methods of producing a color filter used for liquid crystal display elements and solid state image pick-up elements, a dyeing method, a printing method, an electrodepositing method and a pigment dispersion method are known.

In the pigment dispersion method, the color filter is produced by a photolithographic method using a colored radiation-sensitive composition prepared by dispersing a pigment in any one of various types of photosensitive compositions. The color filter produced by this method is stable with respect to light, heat and the like since the pigment is used. A high positional accuracy can be obtained in this method since patterning is performed by the photolithographic method and, accordingly, this method has widely been used as a method suitable for producing the color filter for a large screen and high fineness color display.

In a case in which the color filter is produced by the pigment dispersion method, the radiation-sensitive composition is first coated on a glass substrate by using, for example, a spin coater or a roll coater and, then, dried, to thereby form a coating film. Then, colored pixels are obtained by pattern-exposing and developing the thus-formed coating film. The color filter can be obtained by repeating such operation as described above by the number of different colors.

As for the pigment dispersion method, a method which uses a negative photosensitive composition comprising an alkali-soluble resin together with a photopolymerizable monomer and a photopolymerization initiator is proposed in each of, for example, JP-A Nos. 2-181704, 2-199403, 5-273411 and 7-140654.

On the other hand, the color filter for the solid state image pick-up element has been required to be finer in recent years. However, it is difficult to further improve resolution of the color filter according to the conventional pigment dispersion system. This is because the pigment dispersion method is not suitable for an application requiring a fine patterning such as the solid state image pick-up element since color unevenness occurs due to coarse pigment particles.

In order to solve the aforementioned problems, a technique using a dye instead of the pigment is proposed in JP-A No. 6-75375. However, a problem arises that a dye-containing curable composition is generally inferior to a pigment-containing curable composition in various types of properties such as light fastness, heat resistance, solubility and coating evenness. Further, in a case in which the dye-containing curable composition is used in forming the color filter for the solid state image pick-up element, since a film thickness as thin as 1.5 μm or less is particularly required, it is necessary to incorporate a large amount of dye into the curable composition and such incorporation causes other problems of an insufficient adhesion with the substrate, an insufficient curing and bleaching of the dye in an exposed portion and, then, it becomes extremely difficult to attain a rectangular profile of a pattern shape.

### SUMMARY OF THE INVENTION

An object of the invention is to provide a negative dye-containing curable composition which is favorable in use of a dye, excellent in a rectangular profile of a pattern shape and has a wide latitude against a development time period and a color filter using the negative dye-containing curable composition. Another object of the present invention is to provide a method of producing an excellent color filter with a high cost performance.

A first aspect of the invention is to provide a negative dye-containing curable composition, comprising an alkali-soluble binder, an organic solvent-soluble dye, a photopolymerizable compound, a photopolymerization initiator, an organic solvent and at least one compound selected from the group consisting of higher fatty acids and derivatives thereof.

A second aspect of the invention is to provide a color filter, comprising an alkali-soluble binder, an organic solvent-soluble dye and at least one compound selected from the group consisting of higher fatty acids and derivatives thereof.

A third aspect of the invention is to provide a method of producing a color filter, comprising:

applying the negative dye-containing curable composition according to claim 1 on a substrate;

exposing the applied negative dye-containing curable composition through a mask; and

developing the exposed negative dye-containing curable composition to form a pattern.

### DETAILED DESCRIPTION OF THE INVENTION

Hereinafter, a negative dye-containing curable composition of the present invention, a color filter to be constituted by using the negative dye-containing curable composition and a method of producing the color filter will be described in detail.

<<Negative Dye-Containing Curable Composition>>

A negative dye-containing curable composition of the present invention comprises (1) an alkali-soluble binder, (2) an organic solvent-soluble dye, (3) a photopolymerizable compound, (4) a photopolymerization initiator, (5) an organic solvent and (6) at least one of a higher fatty acid and derivative thereof (hereinafter, referred to simply as “higher fatty acid according to the present invention”) and may further comprise other components such as a cross-linking agent and the like.

According to the present invention, by using the higher fatty acid according to the present invention simultaneously with a dye, a rectangular profile of a pattern shape of the negative dye-containing curable composition can be improved. Further, the negative dye-containing curable composition of the present invention has a wide latitude against a development time period and, accordingly, even when the development time period is extended, the rectangular profile of the pattern shape can favorably be maintained.

(1) Alkali-Soluble Binder

Hereinafter, the alkali-soluble binder will be described. The alkali-soluble binder according to the present invention is not particularly restricted, so long as it is soluble in water or an alkali. However, it is preferable that the alkali-soluble binder is selected from the viewpoint of heat resistance, development ability, availability and the like.

The alkali-soluble binder is preferably a linear organic polymer that is soluble in an organic solvent and developable with a weak alkali aqueous solution. Examples of the linear organic polymer include a polymer having a carboxylic acid on a side chain, such as a methacrylic acid copolymer, an acrylic acid copolymer, an itaconic acid copolymer, a crotonic acid copolymer, a maleic acid copolymer and a partially esterified maleic acid copolymer, described, for example, in JP-A No. 59-44615, JP-B Nos. 54-34327,58-12577 and 54-25957, and JP-A Nos. 59-53836 and 59-71048, and also, an acidic cellulose derivative having a carboxylic acid on a side chain is useful.

In addition to the foregoing, a polymer obtained by adding an acid anhydride to a polymer having a hydroxyl group, a polyhydroxystyrene resin, a polysiloxane resin, poly(2-hydroxyethyl (meth)acrylate), polyvinylpyrrolidone, polyethyleneoxide and polyvinyl alcohol are also useful.

A monomer having a hydrophilic group may be copolymerized, and examples thereof include alkoxyalkyl (meth)acrylate, hydroxyalkyl (meth)acrylate, glycerol (meth)acrylate, (meth)acrylamide, N-methylolacrylamide, secondary or tertiary alkylacrylamide, dialkylaminoalkyl (meth)acrylate, morpholine (meth)acrylate, N-vinylpyrrolidone, N-vinylcaprolactam, vinylimidazole, vinyltriazole, methyl (meth)acrylate, ethyl (meth)acrylate, branched or linear propyl (meth)acrylate, branched or linear butyl (meth)acrylate and phenoxyhydroxypropyl (meth)acrylate.

Furthermore, a monomer having a tetrahydrofurfuryl group, phosphoric acid, a phosphate ester, a quaternary ammonium salt, an ethyleneoxy chain, a propyleneoxy chain, sulfonic acid or a salt thereof, or a morpholinoethyl group is also useful as the monomer having a hydrophilic group.

Further, in order to improve a cross-linking efficiency, the alkali-soluble binder may have a polymerizable group in a side chain, and a polymer having an allyl group, a (meth)acrylic group or an allyloxy alkyl group in a side chain or the like is also useful as the alkali-soluble binder. Examples of such polymers each having the polymerizable group include KS Resist-106 (trade name; manufactured by Osaka Organic Chemical Industry Ltd.) and Cyclomer P Series (trade name; manufactured by Daicel Chemical Industries, Ltd.) which are commercially available. Still further, in order to increase strength of a cured film, alcohol-soluble nylon, a polyether of 2,2-bis-(4-hydroxyphenyl)-propane and epichlorohydrin and the like are also useful as the alkali-soluble binder according to the present invention.

Among these various kinds of alkali-soluble binders, a polyhydroxystyrene resin, a polysiloxane resin, an acrylic resin, an acrylamide resin and an acrylic/acrylamide copolymer resin are preferred from the standpoint of heat resistance, and an acrylic resin, an acrylamide resin and an acrylic/acrylamide copolymer resin are preferred from the standpoint of controllability of developing property.

Preferable examples of such acrylic resins as described above include a copolymer comprising a monomer selected from among benzyl (meth)acrylate, (meth)acrylic acid, hydroxyethyl (meth)acrylate and (meth)acrylic amide, as well as KS Resist-106 (trade name; manufactured by Osaka Organic Chemical Industry Ltd.) and Cyclomer P series (Daicel Chemical Industries, Ltd.) which are commercially available.

The alkali-soluble binder is preferably a polymer having a weight average molecular weight (a value in terms of polystyrene measured by using a GPC method) in the range of from 1000 to 2×10⁵, more preferably in the range of from 2000 to 1×10⁵ and, particularly preferably, in the range of from 5000 to 5×10⁴.

A content of the alkali-soluble binder in the negative dye-containing curable composition of the present invention is, based on the total solid content (mass) of the composition, preferably in the range of from 10% by mass to 90% by mass, more preferably in the range of 20% by mass to 80% by mass and, particularly preferably, in the range of from 30% by mass to 70% by mass.

(2) Organic Solvent-Soluble Dye

The organic solvent-soluble dye according to the present invention is not particularly restricted, so long as it is soluble in an organic solvent. For example, a conventionally known dye for color filter can be used. Specific examples of such organic solvent-soluble dyes include coloring matters as described in JP-A Nos. 64-90403, 64-91102, 1-94301 and 6-11614; Japanese Patent No. 2592207; U.S. Pat. Nos. 4,808,501, 5,667,920 and 5,059,500; and JP-A Nos. 5-333207, 6-35183, 6-51115 and 6-194828. From the standpoint of a chemical structure, dyes of a triphenylmethane type, an anthraquinone type, a benzylidene type, an oxonol type, a cyanine type, a phenothiazine type, a pyrrolopyrazole azomethin type, a xanthene type, a phthalocyanine type, a benzopyran type, an indigo type and the like can be used. The organic solvent-soluble dyes are, particularly preferably, those of a pyrazoleazo type, an anilinoazo type, a pyrazolotriazoleazo type, a pyridoneazo type, an anthraquinone type and an anthrapyridone type.

Further, in a case of a resist system in which development is performed in water or an alkali, an acid dye or a derivative thereof can favorably be used from the viewpoint of completely removing at least one of the alkali-soluble binder and dye by the development. Other than these dyes, at least one of a direct dye, a basic dye, a mordant dye, an acid mordant dye, an azoic dye, a disperse dye, an oil-soluble dye, a food dye and derivatives thereof can also be usefully employed.

-Acid Dye-

The acid dye will be described below. The acid dye is not particularly restricted, so long as it is a dye having an acidic group of, for example, a sulfonic acid or a carboxylic acid, or a phenolic hydroxyl group. However, it is preferable to select the acid dye by taking into consideration all of required properties, such as solubility against an organic solvent or a developer, formability of a salt with a basic compound, light absorbance, an interaction with any one of other components in the curable composition, light fastness and heat resistance.

Although specific examples of such acid dyes are described below, the invention is not restricted to these examples. Examples of the acid dyes include:

acid alizarin violet N;

acid black 1, 2, 24 and 48;

acid blue 1, 7, 9, 15, 18, 23, 25, 27, 29, 40, 42, 45, 51, 62, 70, 74, 80, 83, 86, 87, 90, 92, 96, 103, 112, 113, 120, 129, 138, 147, 150, 158, 171, 182, 192, 210, 242, 243, 256, 259, 267, 278, 280, 285, 290, 296, 315, 324:1, 335 and 340;

acid chrome violet K;

acid Fuchsin;

acid green 1, 3, 5, 9, 16, 25, 27, 50, 58, 63, 65, 80, 104, 105, 106 and 109;

acid orange 6, 7, 8, 10, 12, 26, 50, 51, 52, 56, 62, 63, 64, 74, 75, 94, 95, 107, 108, 169 and 173;

acid red 1, 4, 8, 14, 17, 18, 26, 27, 29, 31, 34, 35, 37, 42, 44, 50, 51, 52, 57, 66, 73, 80, 87, 88, 91, 92, 94, 97, 103, 111, 114, 129, 133, 134, 138, 143, 145, 150, 151, 158, 176, 182, 183, 198, 206, 211, 215, 216, 217, 227, 228, 249, 252, 257, 258, 260, 261, 266, 268, 270, 274, 277, 280, 281, 195, 308, 312, 315, 316, 339, 341, 345, 346, 349, 382, 383, 394, 401, 412, 417, 418, 422 and 426;

acid violet 6B, 7, 9, 17 and 19;

acid yellow 1, 3, 7, 9, 11, 17, 23, 25, 29, 34, 36, 38, 40, 42, 54, 65, 72, 73, 76, 79, 98, 99, 111, 112, 113, 114, 116, 119, 123, 128, 134, 135, 138, 139, 140, 144, 150, 155, 157, 160, 161, 163, 168, 169, 172, 177, 178, 179, 184, 190, 193, 196, 197, 199, 202, 203, 204, 205, 207, 212, 214, 220, 221, 228, 230, 232, 235, 238, 240, 242, 243 and 251;

Direct Yellow 2, 33, 34, 35, 38, 39, 43, 47, 50, 54, 58, 68, 69, 70, 71, 86, 93, 94, 95, 98, 102, 108, 109, 129, 136, 138 and 141;

Direct Orange 34, 39, 41, 46, 50, 52, 56, 57, 61, 64, 65, 68, 70, 96, 97, 106 and 107;

Direct Red 79, 82, 83, 84, 91, 92, 96, 97, 98, 99, 105, 106, 107, 172, 173, 176, 177, 179, 181, 182, 184, 204, 207, 211, 213, 218, 220, 221, 222, 232, 233, 234, 241, 243, 246 and 250;

Direct Violet 47, 52, 54, 59, 60, 65, 66, 79, 80, 81, 82, 84, 89, 90, 93, 95, 96, 103 and 104;

Direct Blue 57, 77, 80, 81, 84, 85, 86, 90, 93, 94, 95, 97, 98, 99, 100, 101, 106, 107, 108, 109, 113, 114, 115, 117, 119, 137, 149, 150, 153, 155, 156, 158, 159, 160, 161, 162, 163, 164, 166, 167, 170, 171, 172, 173, 188, 189, 190, 192, 193, 194, 196, 198, 199, 200, 207, 209, 210, 212, 213, 214, 222, 228, 229, 237, 238, 242, 243, 244, 245, 247, 248, 250, 251, 252, 256, 257, 259, 260, 268, 274, 275 and 293:

Direct Green 25, 27, 31, 32, 34, 37, 63, 65, 66, 67, 68, 69, 72, 77, 79 and 82;

Mordant Yellow 5, 8, 10, 16, 20, 26, 30, 31, 33, 42, 43, 45, 56, 50, 61, 62 and 65;

Mordant Orange 3, 4, 5, 8, 12, 13, 14, 20, 21, 23, 24, 28, 29, 32, 34, 35, 36, 37, 42, 43, 47 and 48;

Mordant Red 1, 2, 3, 4, 9, 11, 12, 14, 17, 18, 19, 22, 23, 24, 25, 26, 30, 32, 33, 36, 37, 38, 39, 41, 43, 45, 46, 48, 53, 56, 63, 71, 74, 85, 86, 88, 90, 94 and 95;

Mordant Violet 2, 4, 5, 7, 14, 22, 24, 30, 31, 32, 37, 40, 41, 44, 45, 47, 48, 53 and 58;

Mordant Blue 2, 3, 7, 8, 9, 12, 13, 15, 16, 19, 20, 21, 22, 23, 24, 26, 30, 31, 32, 39, 40, 41, 43, 44, 48, 49, 53, 61, 74, 77, 83 and 84;

Mordant Green 1, 3, 4, 5, 10, 15, 19, 26, 29, 33, 34, 35, 41, 43 and 53;

Food Yellow 3; and

derivatives thereof.

Among the aforementioned acid dyes, the following dyes and derivatives thereof are preferable:

acid black 24;

acid blue 23, 25, 29, 62, 80, 86, 87, 92, 138, 158, 182, 243 and 324:1;

acid orange 8, 51, 56, 74, 63 and 74;

acid red 1, 4, 8, 34, 37, 42, 52, 57, 80, 97, 114, 143, 145, 151, 183, 217 and 249;

acid violet 7;

acid yellow 17, 25, 29, 34, 42, 72, 76, 99, 111, 112, 114, 116, 134, 155, 169, 172, 184, 220, 228, 230, 232 and 243; and

Acid Green 25; and the like.

Further, other than the aforementioned acid dyes and derivatives thereof, acid dyes of an azo type, a xanthene type and a phthalocyanine type are also preferable. Examples of these acid dyes include C.I. Solvent Blue 44 and 38; C.I. Solvent Orange 45; Rhodamine B and Phodamine 110; 2,7-naphthalenedisulfonic acid; 3-[(5-chloro-2-phenoxyphenyl) hydrazono]-3,4-dihydro-4-oxo-5-[(phenylsulfonyl)amino]; and derivatives thereof.

As for the aforementioned derivatives of acid dyes, an inorganic salt of the acid dye having an acidic group of, for example, a sulfonic acid or a carboxylic acid, a salt of the acid dye with a nitrogen-containing compound, and a sulfonamide of the acid dye (compound having an amido bond to be formed between the acid dye and the nitrogen-containing compound) and the like can be used. The derivatives are not particularly restricted, so long as they are soluble in a solution of the curable composition. However, the acid dye is selected by taking into consideration all of required properties, such as solubility against an organic solvent or a developer, light absorbance, an interaction with any one of other components in the curable composition, light fastness and heat resistance.

The salt of the acid dye with the nitrogen-containing compound will be described below. Forming a salt between the acid dye and the nitrogen-containing compound may be effective for improving solubility (imparting solubility in an organic solvent) of the acid dye, heat resistance and light fastness.

The nitrogen-containing compound that forms a salt with the acid dye, and the nitrogen-containing compound that forms an amide bond with the acid dye will be described below.

The nitrogen-containing compound is selected taking into consideration all of the required properties such as solubility of the salt or the amide compound in the organic solvent or the developer, salt forming ability, light absorbance and a color value of the dye, an interaction between the nitrogen-containing compound and any one of other components in the curable composition, and heat resistance and light fastness as a coloring agent. A molecular weight of the nitrogen-containing compound is preferably as small as possible when the compound is selected considering only the light absorbance and color value. The molecular weight is preferably 300 or less, more preferably 280 or less and, particularly preferably, 250 or less.

A molar ratio (hereinafter, referred to also as “n”) of the nitrogen-containing compound to the acid dye in the salt between the acid dye and nitrogen-containing compound will be described below. The molar ratio n denotes a ratio of an acid dye molecule to an amine compound as a counter ion. The molar ratio n may be freely selected depending on a salt forming condition between the acid dye and the amine compound. Specifically, n is a value satisfying the relation of 0<n≦5 of the number of the functional groups in the acid of the acid dye in most practical cases, and may be selected considering all the required properties such as solubility in the organic solvent or the developer, salt forming ability, light absorbance, an interaction with any one of other components in the curable composition, light fastness and heat resistance. When n is selected from the viewpoint of only the light absorbance, n preferably satisfies the relation of 0<n≦4.5, more preferably 0<n≦4 and, particularly preferably, 0<n≦3.5.

Since the acid dye is prepared by incorporating an acid group into a structure thereof, it can be changed into a non-acid dye by changing a substituent thereof.

The acid dye may favorably act at the time of an alkali development but may sometimes be over-developed. For this account, when the acid dye is in the risk of being over-developed, the non-acid dye is sometimes favorably used.

A concentration of the organic solvent-soluble dye will be described below. While the concentration of the organic solvent-soluble dye in the total solid content of the negative dye-containing curable composition of the present invention differs depending on the kind of the dye, from the standpoint of attaining a balance between a color reproduction property and a hard film forming property, it is preferably in the range of from 0.5% by mass to 80% by mass, more preferably in the range of from 0.5% by mass to 60% by mass and, particularly preferably, in the range of from 0.5% by mass to 50% by mass.

(3) Photopolymerizable Compound

Next, the photopolymerizable compound according to the present invention will be described. The photopolymerizable compound according to the present invention is not particularly restricted, so long as it is a compound capable of being polymerized by a photopolymerization initiator and a radical-polymerizable monomer can favorably be used. The radical-polymerizable monomer is preferably a compound having at least one addition-polymerizable ethylenic double bond and a boiling point of 100° C. or more under normal pressure. The negative dye-containing curable composition of the present invention is constituted such that it has a negative by containing the photopolymerizable compound according to the present invention, together with a photopolymerization initiator to be described below and the like.

Examples of such radical-polymerizable monomers include monofunctional acrylates or methacrylates such as polyethylene glycol mono(meth)acrylate, polypropylene glycol mono(meth)acrylate, and phenoxyethyl (meth)acrylate; polyethylene glycol di(meth)acrylate, trimethylolethane tri(meth)acrylate, neopentylglycol di(meth)acrylate, pentaerythritol tri(meth)acrylate, pentaerythritol tetra(meth)acrylate, dipentaerythritol penta(meth)acrylate, dipentaerythritol hexa(meth)acrylate, hexanediol (meth)acrylate, trimethylolpropane tri(acryloyloxypropyl)ether, tri(acryloyloxyethyl)isocyanulate; (meth)acrylate compounds prepared after an addition reaction of ethylene oxide or propylene oxide to polyfunctional alcohols such as glycerine and trimethylolethane; urethane acrylates as described in JP-B Nos. 48-41708 and 50-6034, and JP-A No. 51-37193; polyester acrylates as described in JP-A No. 48-64183 and JP-B Nos. 49-43191 and 52-30490; a polyfunctional acrylate or methacrylate such as an epoxyacrylate which is a reaction product of an epoxy resin and (meth)acrylic acid; and mixtures thereof. Examples of the radical-polymerizable monomers further include compounds as described in Nihon Secchaku Kyokaishi (Journal of the Adhesion Society of Japan) Vol. 20, No. 7, pp.300 to 308 as a photocurable monomer and an oligomer.

From the standpoint of attaining enhancement of the hardness of the coating film and the rectangular profile, a content of the photopolymerizable compound in the negative dye-containing curable composition of the present invention is, based on the total solid content (mass) of the composition, preferably in the range from 0.1% by mass to 90% by mass, more preferably in the range of from 1.0% by mass to 80% by mass and, particularly preferably, in the range of from 2.0% by mass to 70% by mass.

(4) Photopolymerization Initiator

Next, the photopolymerization initiator according to the present invention will be described. The photopolymerization initiator is contained together with the photopolymerizable compound in order to constitute the negative dye-containing curable composition such that it comes to be of a negative. The photopolymerization initiator is not particularly restricted, so long as it can polymerize the polymerizable compound. The photopolymerization initiator is preferably selected from the viewpoint of its properties, polymerization initiation efficiency, absorbing wavelength, availability, cost and the like.

Examples of such photopolymerization initiators include at least one active halogen compound selected from among halomethyl oxadiazole compounds and halomethyl-s-triazine compounds; 3-aryl substituted coumarin compounds; lophine dimers; benzophenone compounds; acetophenone compounds and derivatives thereof; cyclopentadiene-benzene-iron complexes and salts thereof; and oxime type compounds.

Examples of the active halogen compound as the halomethyloxadiazole compound include 2-halomethyl-5-vinyl-1,3,4-oxadiazole compound described in JP-B No. 57-6096, 2-trichloromethyl-5-styryl-1,3,4-oxadiazole, 2-trichloromethyl-5-(p-cyanostyryl)-1,3,4-oxadiazole and 2-trichloromethyl-5-(p-methoxystyryl)-1,3,4-oxadiazole.

Examples of the active halogen compound as the halomethyl-s-triazine compound include a vinylhalomethyl-s-triazine compound described in JP-B No. 59-1281, and a 2-(naphtho-1-yl)-4,6-bishalomethyl-s-triazine compound and a 4-(p-aminophenyl)-2,6-dihalomethyl-s-triazine compound described in JP-A No. 53-133428.

Specific examples thereof include 2,4-bis(trichloromethyl)-6-p-methoxystyryl-s-triazine, 2,6-bis(trichloromethyl)-4-(3,4-methylenedioxyphenyl)-1,3,5-triazine, 2,6-bis(trichloromethyl)-4-(4-methoxyphenyl)-1,3,5-triazine, 2,4-bis(trichloromethyl)-6-(1-p-dimethylaminophenyl-1,3-butadienyl)-s-triazine, 2-trichloromethyl-4-amino-6-p-methoxystyryl-s-triazine, 2-(naphtho-1-yl)-4,6-bistrichloromethyl-s-triazine, 2-(4-methoxynaphto-1-yl)-4,6-bistrichloromethyl-s-triazine, 2-(4-ethoxynaphtho-1-yl)-4,6-bistrichloromethyl-s-triazine, 2-(4-butoxynaphtho-1-yl)-4,6-bistrichloromethyl-s-triazine, 2-(4-(2-methoxyethyl)-naphto-1-yl)-4,6-bistrichloromethyl-s-triazine, 2-(4-(2-ethoxyethyl)-naphtho-1-yl)-4,6-bistrichloromethyl-s-triazine, 2-(4-(2-butoxyethyl)-naphtho-1-yl)-4,6-bistrichloromethyl-s-triazine, 2-(2-methoxynaphtho-2-yl)-4,6-bistrichloromethyl-s-triazine, 2-(6-methoxy-5-methylnaphtho-2-yl)-4,6-bistrichloromethyl-s-triazine, 2-(6-methoxynaphtho-2-yl)-4,6-bistrichloromethyl-s-triazine, 2-(5-methoxynaphtho-1-yl)-4,6-bistrichloromethyl-s-triazine, 2-(4,7-dimethoxynaphtho-1-yl)-4,6-bistrichloromethyl-s-triazine, 2-(6-ethoxynaphtho-2-yl)-4,6-bistrichloromethyl-s-triazine, 2-(4,5-dimethoxynaphtho-1-yl)-4,6-bistrichloromethyl-s-triazine, 4-(p-N,N-di(ethoxycarbonylmethyl)aminophenyl)-2,6-di(trichloromethyl)-s-triazine, 4-(o-methyl-p-N,N-di(ethoxycarbonylmethyl)aminophenyl)-2,6-di(trichloromethyl)-s-triazine, 4-(p-N,N-di(chloroethyl)aminophenyl)-2,6-di(trichloromethyl)-s-triazine, 4-(o-methyl-p-N,N-di(chloroethyl)aminophenyl)-2,6-di(trichloromethyl)-s-triazine, 4-(p-N-chloroethylaminophenyl)-2,6-di(trichloromethyl)-s-triazine, 4-(p-N-ethoxycabonylmethylaminophenyl)-2,6-di(trichloromethyl)-s-triazine, 4-(p-N,N-di(phenyl)aminophenyl)-2,6-di(trichloroemthyl)-s-triazine, 4-(p-N-chloroethylcarbonylaminophenyl)-2,6-di(trichloromethyl)-s-triazine, 4-(p-N-(p-methoxyphenyl)carbonylaminophenyl)-2,6-di(trichloromethyl)-s-triazine, 4-(m-N,N-di(ethoxycarbonylmethyl)aminophenyl)-2,6-di(trichloromethyl)-s-triazine, 4-(m-bromo-p-N,N-di(ethoxycarbonylmethyl)aminophenyl)-2,6-di(trichloromethyl)-s-triazine, 4-(m-chloro-p-N,N-di(ethoxycarbonylmethyl)aminophenyl)-2,6-di(trichloromethyl)-s-triazine, 4-(m-fluoro-p-N,N-di(ethoxycarbonylmethyl)aminophenyl)-2,6-di(trichloromethyl)-s-triazine, 4-(o-bromo-p-N,N-di(ethoxycarbonylmethyl)aminophenyl)-2,6-di(trichloromethyl)-s-triazine, 4-(o-chloro-p-N,N-di(ethoxycarbonylmethyl)aminophenyl)-2,6-di(trichloromethyl)-s-triazine, 4-(o-fluoro-p-N,N-di(ethoxycarbonylmethyl)aminophenyl-2,6-di(trichloromethyl)-s-triazine, 4-(o-bromo-p-N,N-di(chloroethyl)aminophenyl-2,6-di(trichloromethyl)-s-triazine, 4-(o-chloro-p-N,N-di(chloroethyl)aminophenyl)-2,6-di(trichloromethyl)-s-triazine, 4-(o-fluoro-p-N,N-di(chloroethyl)aminophenyl)-2,6-di(trichloromethyl)-s-triazine, 4-(m-bromo-p-N,N-di(chloroethyl)aminophenyl)-2,6-di(trichloromethyl)-s-triazine, 4-(m-chloro-p-N,N-di(chloroethyl)aminophenyl)-2,6-di(trichloromethyl)-s-triazine, 4-(m-fluoro-p-N,N-di(chloroethyl)aminophenyl)-2,6-di(trichloromethyl)-s-triazine, 4-(m-bromo-p-N-ethoxycarbonylmethylaminophenyl)-2,6-di(trichloromethyl)-s-triazine, 4-(m-chloro-p-N-ethoxycarbonylmethylaminophenyl)-2,6-di(trichloromethyl)-s-triazine, 4-(m-fluoro-p-N-ethoxycarbonylmethylaminophenyl)-2,6-di(trichloromethyl)-s-triazine, 4-(o-bromo-p-N-ethoxycarbonylmethylaminophenyl)-2,6-di(trichloromethyl)-s-triazine, 4-(o-chloro-p-N-ethoxycarbonylmethylaminophenyl)-2,6-di(trichloromethyl)-s-triazine, 4-(o-fluoro-p-N-ethoxycarbonylmethylaminophenyl)-2,6-di(trichloromethyl)-s-triazine, 4-(m-bromo-p-N-chloroethylaminophenyl)-2,6-di(trichloromethyl)-s-triazine, 4-(m-chloro-p-N-chloroethylaminophenyl)-2,6-di(trichloromethyl)-s-triazine, 4-(m-fluoro-p-N-chloroethylaminophenyl)-2,6-di(trichloromethyl)-s-triazine, 4-(o-bromo-p-N-chloroethylaminophenyl)-2,6-di(trichloromethyl)-s-triazine, 4-(o-chloro-p-N-chloroethylaminophenyl)-2,6-di(trichloromethyl)-s-triazine and 4-(o-fluoro-p-N-chloroethylaminophenyl)-2,6-di(trichloromethyl)-s-triazine.

Examples of other photopolymerization initiators which are usefully used and commercially available include TAZ-series manufactured by Midori Kagaku Co., Ltd. (for example, trade name: TAZ-107, TAZ-110, TAZ-104, TAZ-109, TAZ-140, TAZ-204, TAZ-113 and TAZ-123), T-series manufactured by PANCHIM Co. (for example, trade name: T-OMS, T-BMP, T-R and T-B), Irgacure series manufactured by Ciba Specialties Corp. (for example, trade name: Irgacure 651, Irgacure 184, Irgacure 500, Irgacure 1000, Irgacure 149, Irgacure 819 and Irgacure 261), Darocure series (for example, trade name: Darocure 1173), 4,4′-bis(diethylamino)-benzophenone, 2-(o-benzoyloxime)-1-[4-(phenylthio)phenyl]-1,2-octanedione, 2-benzyl-2-dimethylamino-4-morphorinobutylophenone, 2,2-dimethoxy-2-phenylacetophenone, 2-(o-chlorophenyl)-4,5-diphenylimidazolyl dimer, a 2-(o-fluorophenyl)-4,5-diphenylimidazolyl dimer, a 2-(o-methoxyphenyl)-4,5-diphenylimidazolyl dimer, a 2-(p-methoxyphenyl)-4,5-diphenylimidazolyl dimer, a 2-(p-dimethoxyphenyl)-4,5-diphenylimidazolyl dimer, a 2-(2,4-dimethoxyphenyl)-4,5-diphenylimidazolyl dimer, a 2-(p-methylmercaptophenyl)-4,5-diphenylimidazolyl dimer and benzoin isopropyl ether.

The photopolymerization initiator may be used in combination with a sensitizer and a photostabilizer.

Examples thereof include benzoin, benzoin methyl ether, 9-fluorenone, 2-chloro-9-fluorenone, 2-methyl-9-fluorenone, 9-anthrone, 2-bromo-9-anthrone, 2-ethyl-9-anthrone, 9,10-anthraquinone, 2-ethyl-9,10-anthraquinone, 2-t-butyl-9,10-anthraquinone, 2,6-dichloro-9,10-anthraquinone, xanthone, 2-methylxanthone, 2-methoxyxanthone, 2-ethoxyxanthone, thioxanthone, 2,4-diethylthioxanthone, acridone, 10-butyl-2-chloroacridone, benzyl, dibenzylacetone, p-(dimethylamino)phenyl styryl ketone, p-(dimethylamino)phenyl-p-methyl styryl ketone, benzophenone, p-(dimethylamino)benzophenone (or Michler's ketone), p-(diethylamino)benzophenone, benzoanthrone, a benzothiazole compound described in JP-B No. 51-48516, and TINUVIN 1130 and TINUVIN 400.

Other known photopolymerization initiators than such photopolymerization initiators as described above may be used in the negative dye-containing curable composition of the present invention.

Specific examples thereof include a vicinal polyketaldonyl compound described in U.S. Pat. No. 2,367,660, α-carbonyl compounds described in U.S. Pat. Nos. 2,367,661 and 2,367,670, an acyloin ether described in U.S. Pat. No. 2,448,828, an aromatic acyloin compound substituted with an a-hydrocarbon described in U.S. Pat. No. 2,722,512, a multinuclear quinone compound described in U.S. Pat. Nos. 2,951,758, a combination of a triaryllimidazole dimer and p-aminophenyl ketone described in U.S. Pat. No.3,549,367, and a benzothiazole compound and a trihalomethyl-s-triazine compound described in JP-B No. 51-48516.

An total content of the photopolymerization initiator to be used is, based on the total solid content (mass) of the photopolymerizable compound (radical-polymerizable monomer), preferably in the range from 0.01% by mass to 50% by mass, more preferably in the range of from 1% by mass to 30% by mass and, particularly preferably, in the range of from 1% by mass to 20% by mass. When the content thereof is in the range of from 0.01% by mass to 50% by mass, polymerization is facilitated and low film strength to be derived from a low molecular weight can be prevented.

(5) Organic Solvent

The negative dye-containing curable composition of the present invention contains at least one type of organic solvent. The organic solvent is fundamentally not particularly restricted, so long as it satisfies solubility of each component and coating ability of the negative dye-containing curable composition of the present invention. The organic solvent is preferably selected by taking into consideration particularly solubility of the dye and binder, coating ability and safety. When the negative dye-containing curable composition of the present invention is prepared, the composition preferably contains at least two types of organic solvents.

Preferred examples of the organic solvent include an ester compoud, such as an alkyl ester, e.g., ethyl acetate, n-butyl acetate, isobutyl acetate, amyl formate, isoamyl acetate, isobutyl acetate, butyl propionate, isopropyl butyrate, ethyl butyrate, butyl butyrate, an alkyl ester compound, methyl lactate, ethyl lactate, methyl oxyacetate, ethyl oxyacetate, butyl oxyacetate, methyl methoxyacetate, ethyl methoxyacetate, butyl methoxyacetate, methyl ethoxyacetate and ethyl ethoxyacetate; a 3-oxypropionic acid alkyl ester, such as methyl 3-oxypropionate and ethyl 3-oxypropionate, for example, methyl 3-methoxypropionate, ethyl 3-methoxypropionate, methyl 3-ethoxypropionate and ethyl 3-ethoxypropionate, a 2-oxypropionic acid alkyl ester, such as methyl 2-oxypropionate, ethyl 2-oxypropionate and propyl 2-oxypropionate, for example, methyl 2-methoxypropionate, ethyl 2-methoxypropionate, propyl 2-methoxypropionate, methyl 2-ethoxypropionate, ethyl 2-ethoxypropionate, methyl 2-oxy-2-methylpropionate, ethyl 2-oxy-2-methylpropionate, methyl 2-methoxy-2-methylpropionate and ethyl 2-ethoxy-2-methylpropionate, methyl pyruvate, ethyl pyruvate, propyl pyruvate, methyl acetoacetate, ethyl acetoacetate, methyl 2-oxobutanoate and ethyl 2-oxobutanoate; an ether compound such as diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate and propylene glycol monopropyl ether acetate; a ketone compound, such as methyl ethyl ketone, cyclohexanone, 2-heptanone and 3-heptanone, and an aromatic hydrocarbon compound, such as toluene and xylene.

As described above, from the standpoint of solubility of the dye and the alkali-soluble binder, an improvement of a coated face condition and the like, 2 or more types of these organic solvents may be mixed with one another. Particularly, a mixed solution constituted by 2 or more types of organic solvents selected from among methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether and propylene glycol methyl ether acetate is favorably used.

(6) Higher Fatty Acid and Derivative

Next, the higher fatty acid and derivative thereof (hereinafter, referred to also as higher fatty acid according to the present invention, comprehensively) will be explained. The higher fatty acid according to the present invention denotes a chained monocarboxylic acid, being represented by the general chemical formula: R—COOH (R:CH₃(CH₂)ₘ, which has 10 or more carbon atoms in total in a molecule. When it comes to be a chained monocarboxylic acid having less than 10 carbon atoms in a molecule, since curing of the film comes to be insufficient, the effect of the present invention can not fully be executed. As for the higher fatty acid according to the present invention, it has preferably 11 or more carbon atoms in a molecule and, more preferably 13 or more carbon atoms in a molecule. When it has 11 or more carbon atoms, it is particularly effective in facilitating curing of the film. Further, the higher fatty acid according to the present invention is a derivative thereof, carbon atoms in the derivative is not counted in the “total carbon atoms”.

As for the higher fatty acid according to the present invention and derivatives thereof, any higher fatty acid and derivatives thereof can be used without any restrictions, so long as they satisfy the aforementioned conditions. Specific examples of such higher fatty acids include saturated fatty acids such as undecylic acid, lauric acid, tridecylic acid, myristic acid, pentadecylic acid, heptadecylic acid, palmitic acid, stearic acid, nonadecanoic acid, arachic acid, behenic acid, lignoceric acid, cerotic acid, heptacosanoic acid, montanic acid, melissic acid, lacceric acid and derivatives thereof; and unsaturated fatty acids such as undecylenic acid, oleic acid, elaidic acid, cetoleic acid, erucic acid, brassidic acid, sorbic acid, linoleic acid, linolenic acid, arachidonic acid, propiolic acid, stearolic acid, palmitoleic acid, linderic acid, cis-6-hexadecenic acid and derivatives thereof. As for the derivatives, known derivatives can be used without any restrictions, so long as they are known esters, amides, acyl halides, keten dimmers, amines, as well as derivatives described in ordinary literatures and dictionaries related with fatty acids. Among aforementioned derivatives, as for higher fatty acids according to the present invention, compounds selected from among tridecylic acid, pentadecylic acid, heptadecylic acid, palmitic acid, stearic acid, behenic acid, arachic acid, myristic acid, and derivatives thereof are preferred.

As for higher fatty acids according to the present invention, from the standpoint of attaining enhancement of the curing of the film and the rectangular profile, particularly, a saturated fatty acid having 11 or more carbon atoms per molecule or a derivative thereof and, also, an unsaturated fatty acid having 11 or more carbon atoms per molecule or a derivative thereof are preferred. Although these compounds may be used either each individually or in combinations, it is preferable that the saturated fatty acid having 11 or more carbon atoms per molecule or a derivative thereof and the unsaturated fatty acid having 11 or more carbon atoms per molecule or a derivative thereof are simultaneously used.

As for such combinations as described above, specifically, a combination of behenic amide and stearic amide; a combination of palmitic acid and palmitoleic acid; a combination of stearic acid and oleic acid; a combination of lauric acid and linderic acid; and a combination of palmitic acid, methyl palmitate and cis-6-hexadecenic acid are mentioned.

On this occasion, from the standpoint of enhancing curability of the film, adhesiveness with a substrate and compatibility with a resist, a molar ratio (x/y) of the saturated fatty acid (x) to the unsaturated fatty acid (y) is preferably in the range of from 95/5 to 10/90 and, more preferably, in the range of from 80/20 to 50/50.

A content of the higher fatty acid according to the present invention in the negative dye-containing curable composition of the present invention is, based on the total solid content, from the standpoint of attaining the enhancement of curability of the film, preferably in the range of from 0.01% by mass to 60% by mass and, further, from the standpoint of adhesiveness with the substrate or compatibility with the resist, more preferably in the range of from 0.1% by mass to 40% by mass and, particularly preferably, in the range of from 0.15% by mass to 30% by mass.

-Cross-Linking Agent-

According to the present invention, it is possible to obtain a film which has highly been cured by complementally using a cross-linking agent. The cross-linking agent will be described below.

The cross-linking agent capable of being used according to the present invention is not particularly restricted, so long as it can cure a film by a cross-linking reaction, and examples of such cross-linking agents include (a) an epoxy resin; (b) a melamine compound, a guanamine compound, a glycoluryl compound or a urea compound substituted with at least one substituent selected from among a methylol group, an alkoxymethyl group and an acyloxymethyl group; and (c) a phenol compound, a naphthol compound or a hydroxyanthrathene compound substituted with at least one substituent selected from among a methylol group, an alkoxymethyl group and an acyloxymethyl group. Among these cross-linking agents, a multifunctional epoxy resin is particularly preferably used as a cross-linking agent according to the present invention.

The epoxy resin (a) may be any compound that has an epoxy group and crosslinking property, and examples thereof include a divalent glycidyl group-containing low molecular weight compound, such as bisphenol A glycidyl ether, ethylene glycol diglycidyl ether, butanediol diglycidyl ether, hexanediol diglycidyl ether, dihydroxybiphenyl diglycidyl ether, diglycidyl phthalate and N,N-diglycidylaniline, a trivalent glycidyl group-containing low molecular weight compound, such as trimethylolpropane triglycidyl ether, trimethylolphenol triglycidyl ether and TrisP-PA (trisphenol P-PA) triglycidyl ether, a tetravalent glycidyl group-containing low molecular weight compound, such as pentaerythritol tetraglycidyl ether and tetramethylolbisphenol A tetraglycidyl ether, a polyvalent glycidyl group-containing low molecular weight compound, such as dipentaerythritol pentaglycidyl ether and dipentaerythritol hexaglycidyl ether, and a glycidyl group-containing polymer compound, such as polyglycidyl (meth)acrylate and a 1,2-epoxy-4-(2-oxiranyl)cyclohexane adduct of 2,2-bis(hydroxymethyl)-1-butanol.

The number of a methylol group, an alkoxymethyl group and an acyloxymethyl group contained in and substituted on the crosslinking agent (b) is generally from 2 to 6 in the case of the melamine compound and from 2 to 4 in the case of the glycoluril compound, the guanamine compound and the urea compound, and is preferably from 5 to 6 in the case of the melamine compound and from 3 to 4 in the case of the glycoluril compound, the guanamine compound and the urea compound.

Hereinafter, such melamine compound, guanamine compound, glycoluryl compound and urea compound as described in (b) may sometimes be referred to also as a methylol group-containing compound of the category (b), an alkoxymethyl group-containing compound of the category (b) or an acyloxymethyl group-containing compound of the category (b).

The methylol group-containing compound of the category (b) can be obtained by heating an alkoxymethyl group-containing compound in an alcohol in the presence of an acid catalyst, such as hydrochloric acid, sulfuric acid, nitric acid and methanesulfonic acid. The acyloxymethyl group-containing compound of the category (b) can be obtained by mixing and stirring a methylol group-containing compound with an acyl chloride in the presence of a basic catalyst.

Specific examples of the compounds of the category (b) having the aforementioned substituent are shown below.

Examples of the melamine compound include hexamethylolmelamine, hexamethoxymethylmelamine, a compound obtained by methoxymethylating from 1 to 5 methylol groups of hexamethylolmelamine or a mixture thereof, hexamethoxyethylmelamine, hexaacyloxymethylmelamine, and a compound obtained by acyloxymethlating from 1 to 5 methylol groups of hexamethylolmelamine or a mixture thereof.

Examples of the guanamine compound include tetramethylolguanamine, tetramethoxymethylguanamine, a compound obtained by methoxymethylating from 1 to 3 methylol groups of tetramethylolguanamine or a mixture thereof, tetramethoxyethylguanamine, tetraacyloxymethylguanamine, and a compound obtained by acyloxymethylating from 1 to 3 methylol groups of tetramethylolguanamine or a mixture thereof.

Examples of the glycoluril compound include tetramethylolglycoluril, tetramethoxymethylglycoluril, a compound obtained by methoxymethylating from 1 to 3 methylol groups of tetramethylolglycoluril or a mixture thereof, and a compound obtained by acyloxymethylating from 1 to 3 methylol groups of tetramethylolglycoluril or a mixture thereof.

Examples of the urea compound include tetramethylolurea, tetramethoxymethylurea, a compound obtained by methoxymethylating from 1 to 3 methylol groups of tetramethylolurea or a mixture thereof, and tetramethoxyethylurea.

The compounds of the category (b) may be used either each individually or in combinations of 2 or more types.

The cross-linking agent as described in (c), that is, a phenol compound, a naphthol compound or a hydroxyanthracene compound substituted with at least one group selected from a methylol group, an alkoxymethyl group and an acyloxymethyl group can suppress inter-mixing with a overcoat resist by forming cross-links by heating in a same manner as in (b) and further enhance film strength. Hereinafter, such compounds as described above may sometimes be referred to also as a methylol group-containing compound of the category (c), an alkoxymethyl group-containing compound of the category (c) or an acyloxymethyl group-containing compound of the category (c), respectively.

At least two methylol groups, acyloxymethyl groups or alkoxymethyl groups should be contained per one molecule of the cross-linking agent of the category (c). Compounds in which both the 2-position and 4-position of the phenol compound as a frame compound are substituted are preferable from the viewpoint of cross-linking ability by heating and preservation stability. Compounds in which both the ortho-position and para-position relative to the OH group of the naphthol compound or hydroxyanthracene compound as a frame compound are substituted are also preferable. The 3-position or 5-position of the phenol compound may be either substituted or unsubstituted.

Positions except the ortho-position relative to the OH group may be either substituted or unsubstituted in the naphthol compound.

The methylol group-containing compound of the category (c) may be obtained by using a compound having a hydrogen atom at the 2- or 4-position relative to the phenolic OH group as a starting material and, then, allowing the material to react with formalin in the presence of a base catalyst such as sodium hydroxide, potassium hydroxide, ammonia or tetraalkylammonium hydroxide.

The alkoxymethyl group-containing compound of the category (c) may be obtained by heating the methylol group-containing compound of the category (c) in an alcohol in the presence of an acid catalyst such as hydrochloric acid, sulfuric acid, nitric acid or methane sulfonic acid.

The acyloxymethyl group-containing compound of the category (c) may be obtained by allowing the methylol group-containing compound of the category (c) to react with an acyl chloride in the presence of a base catalyst.

Examples of the skeleton compound of the crosslinking agent of the category (c) include a phenol compound, a naphthol compound and a hydroxyanthracene compound, in which the o-positions and the p-positions of the phenolic hydroxyl group are unsubstituted, and examples thereof include phenol, isomers of cresol, 2,3-xylenol, 2,5-xylenol, 3,4-xylenol, 3,5-xylenol, a bisphenol compound, such as bisphenol A, 4,4′-bishydroxybiphenyl, TrisP-PA (produced by Honshu Chemical Industry Co., Ltd.), naphthol, dihydroxynaphthalene and 2,7-dihydroxyanthracene.

As specific examples of the crosslinking agent of the category (c), examples of the phenol compound include trimethylolphenol, tri(methoxymethyl)phenol, a compound obtained by methoxymethylating from 1 to 2 methylol groups of trimethylolphenol, trimethylol-3-cresol, tri(methoxymethyl)-3-cresol, a compound obtained by methoxymethylating from 1 to 2 methylol groups of trimethylol-3-cresol, a dimethylolcresol, such as 2,6-dimethylol-4-cresol, tetramethylolbisophenol A, tetramethoxymethylbisphenol A, a compound obtained by methoxymethlating from 1 to 3 methylol groups of tetramethylolbisphenol A, tetramethylol-4,4′-bishydroxybiphenyl, tetramethoxymethyl-4,4′-bishydroxybiphenyl, a hexamethylol compound of TrisP-PA, a hexamethoxymethyl compound of TrisP-PA, a compound obtained by methoxymethylating from 1 to 5 methylol groups of a hexamethylol compound of TrisP-PA, and bishydroxymethylnaphthalenediol.

Examples of the hydroxyanthracene compound include 1,6-dihydroxymethyl-2,7-dihydroxyanthracene, and examples of the acyloxymethyl group-containing compound include compounds obtained by acyloxymethylating a part or all of the methylol groups of the methylol group-containing compounds.

Preferable compounds among the aforementioned compounds are trimethylol phenol, bis hydroxymethyl-p-cresol, tetramethylol bisphenol A, and a hexamethylol form of Tris P-PA (manufactured by Honshu Chemical Industry Co., Ltd.) or a phenol compound in which methylol groups thereof are substituted with alkoxymethyl groups or another phenol compound in which methylol groups thereof are substituted with both methylol groups and alkoxymethyl groups.

The compounds of the category (c) may be used alone or in combinations.

Although An total content of the cross-linking agent to be used in the negative dye-containing curable composition depends on types of starting materials, from the standpoint of enhancing curability of the coating film, it is, based on the total solid content (mass) of the composition, preferably in the range of from 1% by mass to 70% by mass, more preferably in the range of from 5% by mass to 50% by mass and, particularly preferably in the range of from 7% by mass to 30% by mass.

-Thermal Polymerization Inhibitor-

A thermal polymerization inhibitor is preferably contained in the dye-containing curable composition of the present invention in addition to the aforementioned components. Examples thereof include hydroquinone, p-methoxypehnol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol) and 2-mercaptobeozimidazole as the thermal polymerization inhibitor.

-Various Kinds of Additives-

In the dye-containing curable composition of the present invention, various kinds of additives may be added to the dye-containing curable composition of the present invention depending on necessity, such as a filler, a polymer compound other than those described in the foregoing, a surfactant, an adhesion accelerating agent, an antioxidant, an ultraviolet ray absorbing agent and an aggregation preventing agent. Furthermore, a discoloration preventing agent for the dye may also be added depending on necessity.

Examples of the additives include a filler, such as glass and alumina; a polymer compound other than the binder resin, such as polyvinyl alcohol, polyacrylic acid, polyethylene glycol monoalkyl ether and polyfluoroalkyl acrylate; a surfactant, such as a nonionic surfactant, a cationic surfactant and an anionic surfactant; an adhesion accelerating agent, such as vinyltrimethoxysilane, vinyltriethoxysilane, vinyltris(2-methoxyethoxy)silane, N-(2-amonoethyl)-3-aminopropyldimethylmethoxysilane, N-(2-aminoethyl)-3-aminopropyltrimethyoxysilane, 3-aminopropyltriethoxysilane, 3-glycidoxypropyltrimethoxysilane, 3-glycidoxypropylmethyldimethoxysilane, 2-(3,4-epoxycyclohexyl)ethyltrimethoxysilane, 3-chloropropylmethyldimethoxysilane, 3-chloropropyltrimethoxysilane, 3-methacryloxypropyltrimethoxysilane and 3-mercaptopropyltrimethoxysilane; an antioxidant, such as 2,2-thiobis(4-methyl-6-t-butylphenol) and 2,6-di-t-butylphenol; an ultraviolet ray absorbing agent, such as 2-(3-t-butyl-5-methyl-2-hydroxyphenyl)-5-chlorobenzotriazole and alkoxybenzophenone; and an aggregation preventing agent, such as sodium polyacrylate.

In order to accelerate the dissolution of the non-image area to an alkali solution to attain further improvement of the developing property of the dye-containing curable composition of the present invention, an organic carboxylic acid, preferably a low molecular weight organic carboxylic acid having a molecular weight of 1,000 or less, may be added to the composition.

Specific examples thereof include an aliphatic monocarboxylic acid, such as formic acid, acetic acid, propionic acid, butyric acid, valeric acid, pivalic acid, caproic acid, diethylacetic acid, enanthic acid and caprylic acid; an aliphatic dicarboxylic acid, such as oxalic acid, malonic acid, succinic acid, glutaric acid, adipic acid, pimelic acid, suberic acid, azelaic acid, sebacic acid, brassylic acid, methylmalonic acid, ethylmalonic acid, dimethylmalonic acid, methylsuccinic acid, tetramethylsuccinic acid and citraconic acid; an aliphatic tricarboxylic acid, such as tricarballylic acid, aconitic acid and camphoronic acid; an aromatic monocarboxylic acid, such as benzoic acid, toluic acid, cuminic acid, hemellitic acid and mesitylenic acid; an aromatic polycarboxylic acid, such as phthalic acid, isophthalic acid, terephthalic acid, trimellitic acid, trimesic acid, mellophanic acid and pyromellitic acid; and other carboxylic acids, such as phenylacetic acid, hydratropic acid, hydrocinnamic acid, mandelic acid, phenylsuccinic acid, atropic acid, cinnamic acid, methyl cinnamate, benzyl cinnamate, cinnamylideneacetic acid, coumaric acid and umbellic acid.

<<Color Filter and Production Method Thereof>>

The color filter of the present invention will be described in detail with reference to the production process thereof. the dye-containing curable composition of the present invention The color filter of the present invention comprising at least an alkali-soluble binder, an organic solvent-soluble dye and at least one compound selected from the group consisting of higher fatty acids and derivatives thereof.

In the process for producing a color filter of the present invention, a color filter can be produced by using the negative dye-containing curable composition of the present invention.

The negative dye-containing curable composition is coated on a substrate by a coating method, such as spin coating, flow coating and roll coating, to form a radiation sensitive composition layer, which is then exposed through a prescribed mask pattern, followed by being developed with a developer, to form a negative colored pattern (image forming step). The process may further contain, depending on necessity, a curing step for curing the thus formed colored pattern by heating and/or exposure.

The color filter comprising desired hues may be produced by repeating the aforementioned image forming steps (and curing step, if necessary) by the number of the hues. As for light or radiation to be used on this occasion, ultraviolet light, particularly, a g ray, an h ray, an i ray or the like is favorably used.

Examples of the substrate include soda glass, PYREX™ (R) glass and quartz glass, which are used in a liquid crystal display device or the like, those having a transparent electroconductive film adhered, and a photoelectric conversion element substrate, such as a silicon substrate, and a complementary metallic oxide semiconductor (CMOS), which are used in a solid state image sensing device or the like. There are some cases where black stripes for separating pixels are formed on the substrate.

An undercoating layer may be provided, depending on necessity, on the substrate for improvement of adhesion to the upper layer, prevention of diffusion of substances, and planarization of the surface of the substrate.

The developer may be any one that has such a formulation that dissolves an uncured part of the dye-containing curable composition of the present invention but does not dissolve a cured part thereof. Specific examples thereof include a combination of various kinds of organic solvents and an alkali aqueous solution. Examples of the organic solvent include those having been described for preparation of the dye-containing curable composition of the present invention.

Preferred examples of the alkali aqueous solution include alkali aqueous solutions obtained by dissolving such an alkali compound to a concentration of 0.001 to 10% by mass, and preferably from 0.01 to 1% by mass, as sodium hydroxide, potassium hydroxide, sodium carbonate, sodium silicate, sodium metasilicate, aqueous ammonia, ethylamine, diethylamine, dimethylmethanolamine, tetramethylammonium hydroxide, tetraethylammonium hydroxide, choline, pyrrole, piperidine and 1,8-diazabicyclo-(5.4.0)-7-undecene. In the case where a developer containing the alkali aqueous solution is used, the layer thus developed is generally washed with water.

The color filter of the present invention can be used in a liquid crystal display (LCD) or a solid state image pick-up element such as CCD or CMOS. The color filter is suitable for a high resolution CCD element or CMOS having 1,000,000 or more pixels. The color filter of the present invention may be used by being interposed between light-receiving portions of the pixels constituting the CCD and micro-lenses for converging light.

### EXAMPLES

While the present invention is described in detail with reference to embodiments, the invention is not restricted thereto , so long as it does not depart from the scope and spirit of the present invention. Further, all “parts” and “percentages” as used in the examples are given by mass, unless otherwise stated.

### Example 1

1) Preparation of Negative Dye-Containing Curable Composition A

Compounds in a composition as described below were mixed and dissolved, to thereby prepare a negative dye-containing curable composition A.

[Composition]

| | |
|---|---|
| Ethyl lactate | 43.5 parts |
| Allyl methacrylate/methacrylic acid copolymer | 4.1 parts |
| (molar ratio of 80/20) (alkali-soluble binder) | |
| Dipentaerythritol hexaacrylate | 6.1 parts |
| Polymerization inhibitor (p-methoxyphenol) | 0.0061 part |
| Photopolymerization initiator (trade name: TAZ-107; | 1.0 part |
| manufactured by Midori Kagaku Co., Ltd.) | |
| Organic solvent-soluble dye (Valifast yellow 1101) | 7.0 parts |
| Palmitic acid (higher fatty acid of the present invention) | 2.0 parts |

2) Preparation of Silicon Wafer Provided with Undercoat Layer

A resist solution (trade name: CT-2000; manufactured by Fuji Film Arch Co., Ltd.) was applied on a 6-inch silicon wafer by using a spin coater such that the resultant film has a thickness of 2 μm. After such application, the silicon wafer was dried for one hour at 220° C. to form a cured film (undercoat layer) on the wafer.

3) Exposure and Development of Negative Dye-Containing Curable Composition (Image Forming Step)

The negative dye-containing curable composition A which had been obtained in 1) was applied on the silicon wafer having the undercoat layer which had been obtained in 2) by using a spin coater such that the resultant film has a thickness of 1 μm and, then, pre-baked for 120 seconds at 120° C.

Next, light having a wavelength of 365 nm was irradiated on the film by using an i-ray stepper exposure device, to thereby perform a 2-μm pattern exposure. After the exposure, the film was developed for 60 seconds at 23° C. by using a developer (trade name; CD-2000; manufactured by Fuji Film Arch Co., Ltd.). Subsequently, the silicon wafter was rinsed with running water for 20 seconds, subjected to spray drying, to thereby obtain a pattern image A on the wafer. Thereafter, the wafer was heated for 10 minutes at 200° C., to thereby obtain a final image B (color filter).

### Example 2

An image (color filter) was obtained in a same manner as in Example 1 except that a negative dye-containing curable composition B having a composition as described below was used in place of the negative dye-containing curable composition A.

[Composition of Negative Dye-Containing Curable Composition B]

| | |
|---|---|
| Ethyl lactate | 43.5 parts |
| Allyl methacrylate/methacrylic acid copolymer | 4.1 parts |
| (molar ratio of 80/20) (alkali-soluble binder) | |
| Dipentaerythritol hexaacrylate | 6.1 parts |
| Polymerization inhibitor (p-methoxyphenol) | 0.0061 part |
| Photopolymerization initiator (trade name: TAZ-107; | 1.0 part |
| manufactured by Midori Kagaku Co., Ltd.) | |
| Organic solvent-soluble dye (Valifast yellow 1101) | 7.0 parts |
| Dodecyl stearate (higher fatty acid of the present invention) | 2.0 parts |

### Example 3

An image (color filter) was obtained in a same manner as in Example 1 except that a negative dye-containing curable composition C having a composition as described below was used in place of the negative dye-containing curable composition A.

[Composition of Negative Dye-Containing Curable Composition C]

| | |
|---|---|
| Ethyl lactate | 43.5 parts |
| Allyl methacrylate/methacrylic acid copolymer | 4.1 parts |
| (molar ratio of 80/20) (alkali-soluble binder) | |
| Dipentaerythritol hexaacrylate | 6.1 parts |
| Polymerization inhibitor (p-methoxyphenol) | 0.0061 part |
| Photopolymerization initiator (trade name: TAZ-107; | 1.0 part |
| manufactured by Midori Kagaku Co., Ltd.) | |
| Organic solvent-soluble dye (Valifast yellow 1101) | 7.0 parts |
| Behenic amide (higher fatty acid of the present invention) | 1.0 part |
| Stearic acid (higher fatty acid of the present invention) | 1.0 part |

### Example 4

An image (color filter) was obtained in a same manner as in Example 1 except that a negative dye-containing curable composition D having a composition as described below was used in place of the negative dye-containing curable composition A.

[Composition of Negative Dye-Containing Curable Composition D]

| | |
|---|---|
| Ethyl lactate | 43.5 parts |
| Allyl methacrylate/methacrylic acid copolymer | 4.1 parts |
| (molar ratio of 80/20) (alkali-soluble binder) | |
| Dipentaerythritol hexaacrylate | 6.1 parts |
| Polymerization inhibitor (p-methoxyphenol) | 0.0061 part |
| Photopolymerization initiator (trade name: TAZ-107; | 1.0 part |
| manufactured by Midori Kagaku Co., Ltd.) | |
| Organic solvent-soluble dye (Valifast yellow 1101) | 7.0 parts |
| Methyl stearate (higher fatty acid of the present invention) | 2.0 parts |

### Example 5

An image (color filter) was obtained in a same manner as in Example 1 except that a negative dye-containing curable composition E having a composition as described below was used in place of the negative dye-containing curable composition A.

[Composition of Negative Dye-Containing Curable Composition E]

| | |
|---|---|
| Ethyl lactate | 43.5 parts |
| Allyl methacrylate/methacrylic acid copolymer | 4.1 parts |
| (molar ratio of 80/20) (alkali-soluble binder) | |
| Dipentaerythritol hexaacrylate | 6.1 parts |
| Polymerization inhibitor (p-methoxyphenol) | 0.0061 part |
| Photopolymerization initiator (trade name: TAZ-107; | 1.0 part |
| manufactured by Midori Kagaku Co., Ltd.) | |
| Organic solvent-soluble dye (Valifast yellow 1101) | 7.0 parts |
| Ethyl palmitate (higher fatty acid of the present invention) | 2.0 parts |

### Example 6

An image (color filter) was obtained in a same manner as in Example 1 except that a negative dye-containing curable composition F having a composition as described below was used in place of the negative dye-containing curable composition A.

[Composition of Negative Dye-Containing Curable Composition F]

| | |
|---|---|
| Ethyl lactate | 43.5 parts |
| Allyl methacrylate/methacrylic acid copolymer | 4.1 parts |
| (molar ratio of 80/20) (alkali-soluble binder) | |
| Dipentaerythritol hexaacrylate | 6.1 parts |
| Polymerization inhibitor (p-methoxyphenol) | 0.0061 part |
| Photopolymerization initiator (trade name: TAZ-107; | 1.0 part |
| manufactured by Midori Kagaku Co., Ltd.) | |
| Organic solvent-soluble dye (Valifast yellow 1101) | 7.0 parts |
| Ethyl behenate (higher fatty acid of the present invention) | 2.0 parts |

### Comparative Example 1

An image (color filter) was obtained in a same manner as in Example 1 except that a negative dye-containing curable composition for comparison G having a composition as described below was used in place of the negative dye-containing curable composition A.

[Composition of Negative Dye-Containing Curable Composition for Comparison G]

| | |
|---|---|
| Ethyl lactate | 36.9 parts |
| Allyl methacrylate/methacrylic acid copolymer | 4.8 parts |
| (molar ratio of 80/20) (alkali-soluble binder) | |
| Dipentaerythritol hexaacrylate | 7.1 parts |
| Polymerization inhibitor (p-methoxyphenol) | 0.0061 part |
| Photopolymerization initiator (trade name: TAZ-107; | 1.0 part |
| manufactured by Midori Kagaku Co., Ltd.) | |
| Organic solvent-soluble dye (Valifast yellow 1101) | 7.0 parts |

### Comparative Example 2

An image (color filter) was obtained in a same manner as in Example 1 except that a negative dye-containing curable composition for comparison H having a composition as described below was used in place of the negative dye-containing curable composition A.

[Composition of Negative Dye-Containing Curable Composition for Comparison H]

| | |
|---|---|
| Ethyl lactate | 43.5 parts |
| Allyl methacrylate/methacrylic acid copolymer | 4.1 parts |
| (molar ratio of 80/20) (alkali-soluble binder) | |
| Dipentaerythritol hexaacrylate | 6.1 parts |
| Polymerization inhibitor (p-methoxyphenol) | 0.0061 part |
| Photopolymerization initiator (trade name: TAZ-107; | 1.0 part |
| manufactured by Midori Kagaku Co., Ltd.) | |
| Organic solvent-soluble dye (Valifast yellow 1101) | 7.0 parts |
| Butyric acid | 2.0 parts |

4) Evaluation
(1) Rectangular Profile of Pattern

In regard to the thus-obtained images (patterns), a comparison of a rectangular profile of pattern was performed by an SEM photograph observation between the image A after being developed and the image B after being further subjected to a heating treatment. The rectangular profile of pattern was judged by digitalizing the rectangular profile by using a distance of from a center to a top point of a film in a cross-sectional photograph of a pattern of 1 μm long×2 μm wide obtained by a cross-sectional SEM. When the pattern has an ideal rectangle, there is no roundness in a corner subjected to judgment and a distance from the center to the corner comes to be √((0.5)²+(1.0)²)=1.12. For this account, it is found that, as the distance is closer to 1.12, the pattern is excellent in a rectangular profile. Further, in each of Examples and Comparative Examples, a development time period is extended by 30 seconds (to be totally 90 seconds) and, then, the comparison of the rectangular profile of the resultant image C was also performed by the SEM photograph observation in a same manner as in the aforementioned case.

TABLE 1

| | Evaluation of rectangular profile of pattern | | |
|---|---|---|---|
| | Image A | Image B | Image C (developed |
| | (after development) | (after heating) | for 90 seconds) |
| Example 1 | 1.130 | 1.100 | 1.110 |
| Example 2 | 1.040 | 1.050 | 1.030 |
| Example 3 | 1.080 | 1.070 | 1.070 |
| Example 4 | 1.040 | 1.000 | 1.020 |
| Example 5 | 0.990 | 0.960 | 0.970 |
| Example 6 | 1.085 | 1.080 | 1.080 |
| Comparative | 0.750 | 0.700 | 0.250 |
| Example 1 | | | |
| Comparative | 0.620 | 0.600 | 0.205 |
| Example 2 | | | |

As shown in Table 1, it is found that, in Examples which use the higher fatty acid according to the present invention, the rectangular profile of the pattern is extremely favorable and, further, a change thereof by heating after development is extremely small and, therefore, the Examples are favorable. It is also found that the rectangular profile of the pattern at the time of development even for 90 seconds is favorable and, therefore, a latitude against a development time period has been extended. On the other hand, in regard to Comparative Example 1 which does not use the higher fatty acid according to the present invention and Comparative Example 2 which uses a lower fatty acid, in each of cases of after development and after heating, the rectangular profile of the pattern was inferior and, further, the latitude against the development time period was narrow.

Further, other compounds described in the examples of higher fatty acids according to the present invention were also evaluated in a same manner as in Example 1 and, then, it is found that, in each of them, the rectangular profile has been enhanced and the latitude against the development time period has been extended in comparison with Comparative Example 1 and 2.

As has been described above, according to the present invention, a negative dye-containing curable composition which is favorable in use of a dye, excellent in a rectangular profile of pattern and has a wide latitude against a development time period, a color filter using the negative dye-containing curable composition and a method of producing the color filter can be provided.

1. A negative dye-containing curable composition, comprising an alkali-soluble binder, an organic solvent-soluble dye, a photopolymerizable compound, a photopolymerization initiator, an organic solvent and at least one compound selected from the group consisting of higher fatty acids and derivatives thereof.

2. The negative dye-containing curable composition according to claim 1, wherein the number of total carbon atoms per molecule of the higher fatty acid or derivative thereof is 11 or more.

3. The negative dye-containing curable composition according to claim 1, wherein at least one compound selected from the group consisting of higher fatty acids and derivatives thereof is a saturated fatty acid having 11 or more carbon atoms in total per molecule or a derivative thereof.

4. The negative dye-containing curable composition according to claim 1, wherein at least one compound selected from the group consisting of higher fatty acids and derivatives thereof is an unsaturated fatty acid having 11 or more carbon atoms in total per molecule or a derivative thereof.

5. The negative dye-containing curable composition according to claim 1, wherein higher fatty acids and derivatives thereof comprise both a saturated fatty acid having 11 or more carbon atoms in total per molecule or a derivative thereof; and an unsaturated fatty acid having 11 or more carbon atoms in total per molecule or a derivative thereof.

6. The negative dye-containing curable composition according to claim 1, wherein higher fatty acids and derivatives thereof comprise both: a saturated fatty acid having 11 or more carbon atoms in total per molecule or a derivative thereof [x]; and an unsaturated fatty acid having 11 or more carbon atoms in total per molecule or a derivative thereof [y]; at a molar ratio [x/y] in the range of from 95/5 to 10/90.

7. The negative dye-containing curable composition according to claim 1, wherein higher fatty acids and derivatives thereof comprise both: a saturated fatty acid having 11 or more carbon atoms in total per molecule or a derivative thereof [x]; and an unsaturated fatty acid having 11 or more carbon atoms in total per molecule or a derivative thereof [y]; at a molar ratio [x/y] in the range of from 80/20 to 50/50.

8. The negative dye-containing curable composition according to claim 1, wherein a content of the higher fatty acid and derivative thereof is in the range, based on the total solid content, of from 0.01% by mass to 60% by mass.

9. The negative dye-containing curable composition according to claim 1, wherein a content of the higher fatty acid and derivative thereof is in the range, based on the total solid content, of from 0.1% by mass to 40% by mass.

10. The negative dye-containing curable composition according to claim 1, wherein the at least one compound selected from the group consisting of higher fatty acids and derivatives thereof is a compound selected from the group consisting of tridecylic acid, pentadecylic acid, heptadecylic acid, palmitic acid, stearic acid, behenic acid, arachic acid, myristic acid and derivatives thereof.

11. The negative dye-containing curable composition according to claim 1, wherein higher fatty acids and derivatives thereof comprise at least one combination selected from the group consisting of a combination of behenic amide and stearic amide; a combination of palmitic acid and palmitoleic acid; a combination of stearic acid and oleic acid; a combination of lauric acid and linderic acid and; a combination of palmitic acid, methyl palmitate and cis-6-hexadecenic acid.

12. A color filter, comprising an alkali-soluble binder, an organic solvent-soluble dye and at least one compound selected from the group consisting of higher fatty acids and derivatives thereof.

13. A method of producing a color filter, comprising:
applying the negative dye-containing curable composition according to claim 1 on a substrate;
exposing the applied negative dye-containing curable composition through a mask; and
developing the exposed negative dye-containing curable composition to form a pattern.
